(19) United States
(12) Patent Application Publication
(10) Pub. No.: US 2023/0114418 A1
(43) Pub. Date: Apr. 13, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventor: CHIH-CHENG LIU, Hefei City (CN)

(73) Assignee: CHANGXIN MEMORY TECHNOLOGIES, INC., Hefei City (CN)

(21) Appl. No.: 17/805,850

(22) Filed: Jun. 7, 2022

Related U.S. Application Data
(63) Continuation of application No. PCT/CN2021/137432, filed on Dec. 13, 2021.

(30) Foreign Application Priority Data
Oct. 13, 2021 (CN) 202111190824.6

(51) Int. Cl. H01L 29/78; H01L 23/48; H01L 21/768

(52) U.S. Cl. CPC H01L 29/7845; H01L 21/76898; H01L 23/481

(57) ABSTRACT

A semiconductor structure includes: a substrate; a conductive via, a first conductive type transistor, and a second conductive type transistor located in substrate; a first metal layer located on substrate; and a second metal layer located on first metal layer. The first conductive type transistor is disposed on two sides of conductive via in first direction, and second conductive type transistor is disposed on two other sides of conductive via in a second direction perpendicular to first direction. The first metal layer includes at least one first metal line extending in first direction and electrically connected to a gate of first conductive type transistor. The second metal layer includes at least one second metal line extending in second direction and electrically connected to a gate of second conductive type transistor. The first metal line and second metal line intersect with each other to form a grid structure covering conductive via.

### CROSS-REFERENCE TO RELATED APPLICATIONS

This application is a continuation application of International Patent Application No. PCT/CN2021/137432 filed on Dec. 13, 2021, which claims priority to Chinese Patent Application No. 202111190824.6 filed on Oct. 13, 2021. The disclosures of these applications are hereby incorporated by reference in their entirety.

### BACKGROUND

A vertical interconnect stacking packaging method based on a conductive via (for example, Through Silicon Via (TSV)) interconnect technology gradually becomes the development trend of packaging technologies due to its advantages of short-range interconnection and high-density integration.

However, a conductive via tends to protrude outward from a substrate after thermal expansion, which affects the flatness of the substrate and therefore the performance of a semiconductor structure.

### SUMMARY

The disclosure relates to the field of semiconductor manufacturing, and in particular, to a semiconductor structure and a method for manufacturing a semiconductor structure.

In view of this, embodiments of the disclosure provide a semiconductor structure and a method for manufacturing a semiconductor structure to resolve at least one problem in the related art.

The technical solution of the disclosure is implemented as follows. The embodiments of the disclosure provide a semiconductor structure, including:
a substrate;
a conductive via, a first conductive type transistor, and a second conductive type transistor that are located in the substrate, in which the first conductive type transistor is disposed on two sides of the conductive via in a first direction, the second conductive type transistor is disposed on two other sides of the conductive via in a second direction, and the first direction is perpendicular to the second direction;
a first metal layer located on the substrate, in which the first metal layer includes at least one first metal line extending in the first direction, and the first metal line is electrically connected to a gate of the first conductive type transistor; and
a second metal layer located on the first metal layer, in which the second metal layer includes at least one second metal line extending in the second direction, and the second metal line is electrically connected to a gate of the second conductive type transistor,
in which the first metal line and the second metal line intersect with each other to form a grid structure covering the conductive via.

The embodiments of the disclosure further provide a method for manufacturing a semiconductor structure including the following operations.

A substrate is provided, in which the substrate includes a preset area in which a conductive via is formed.

A first conductive type transistor and a second conductive type transistor are formed in the substrate, in which the first conductive type transistor is disposed on two sides of the preset area in a first direction, the second conductive type transistor is disposed on two other sides of the preset area in a second direction, and the first direction is perpendicular to the second direction.

A conductive via is formed in the preset area of the substrate.

A first metal layer is formed on the substrate, in which the first metal layer includes at least one first metal line extending in the first direction, and the first metal line is electrically connected to a gate of the first conductive type transistor.

A second metal layer is formed on the first metal layer, in which the second metal layer includes at least one second metal line extending in the second direction, and the second metal line is electrically connected to a gate of the second conductive type transistor.

The first metal line and the second metal line intersect with each other to form a grid structure covering the conductive via.

### BRIEF DESCRIPTION OF THE DRAWINGS

To describe the technical solutions of the embodiments of the disclosure more clearly, the following briefly describes the accompanying drawings required for the embodiments. Apparently, the accompanying drawings in the following description show only some embodiments of the disclosure, and a person of ordinary skill in the art may still derive other drawings from these accompanying drawings without creative efforts.

FIG. 1 is a schematic diagram of an exemplary semiconductor structure.

FIG. 2A is a schematic top view of a semiconductor structure according to an embodiment of the disclosure.

FIG. 2B is a schematic cross-sectional view of a semiconductor structure according to an embodiment of the disclosure taken along a line A-A′ in FIG. 2A.

FIG. 2C is a schematic cross-sectional view of a semiconductor structure according to an embodiment of the disclosure taken along a line B-B′ in FIG. 2A.

FIG. 3 is a block flowchart of a method for manufacturing a semiconductor structure according to an embodiment of the disclosure.

FIG. 4A is a first schematic cross-sectional view illustrating the operations in a method for manufacturing a semiconductor structure according to an embodiment of the disclosure taken along a line A-A′ in FIG. 2A.

FIG. 4B is a second schematic cross-sectional view illustrating the operations in a method for manufacturing a semiconductor structure according to an embodiment of the disclosure taken along a line A-A′ in FIG. 2A.

FIG. 4C is a third schematic cross-sectional view illustrating the operations in a method for manufacturing a semiconductor structure according to an embodiment of the disclosure taken along a line A-A′ in FIG. 2A.

FIG. 4D is a fourth schematic cross-sectional view illustrating the operations in a method for manufacturing a semiconductor structure according to an embodiment of the disclosure taken along a line A-A′ in FIG. 2A.

FIG. 4E is a fifth schematic cross-sectional view illustrating the operations in a method for manufacturing a semiconductor structure according to an embodiment of the disclosure taken along a line A-A′ in FIG. 2A.

FIG. 4F is a sixth schematic cross-sectional view illustrating the operations in a method for manufacturing a semiconductor structure according to an embodiment of the disclosure taken along a line A-A′ in FIG. 2A.

FIG. 4G is a seventh schematic cross-sectional view illustrating the operations in a method for manufacturing a semiconductor structure according to an embodiment of the disclosure taken along a line A-A′ in FIG. 2A.

FIG. 4H is an eighth schematic cross-sectional view illustrating the operations in a method for manufacturing a semiconductor structure according to an embodiment of the disclosure taken along a line A-A′ in FIG. 2A.

### DETAILED DESCRIPTION

The exemplary embodiments of the disclosure will be more specifically described below with reference to the accompanying drawings. The exemplary embodiments of the disclosure are shown in the accompanying drawings. However, it should be understood that the disclosure may be implemented in various forms, and should not be construed as being limited to the specific embodiments set forth herein. Rather, these embodiments are provided so that the disclosure will be understood more thoroughly, and can fully convey the scope of the disclosure to a person skilled in the art.

In the description below, a large number of specific details are given to provide a more thorough understanding of the disclosure. However, it will be apparent to those skilled in the art that the disclosure can be implemented without one or more of these details. In other examples, to avoid confusion with the disclosure, some technical features that are well known in the art are not described. That is, the full features of actual embodiments are not described here, and functions and structures that are well known are not described in detail.

In the accompanying drawings, the dimensions of the layers, regions, and components, as well as their relative dimensions, may be exaggerated for clarity. The same reference numerals throughout the description indicate the same components.

It should be understood that when an element or layer is referred to as being “on”, “adjacent to”, “connected to”, or “coupled to” another element or layer, it can be directly on, adjacent to, connected to, or coupled to another element or layer, or an intermediate element or layer may be present. In contrast, when an element is referred to as being “directly on”, “directly adjacent to”, “directly connected to”, or “directly coupled to” another element or layer, no intermediate element or layer is present. It should be understood that although the terms first, second, third etc. may be used to describe various elements, components, regions, layers, and/or sections, these elements, components, regions, layers, and/or sections should not be limited by these terms. These terms are only used to distinguish one element, component, region, layer, or section from another element, component, region, layer, or section. Therefore, a first element, component, region, layer, doping type or section discussed below could be termed a second element, component, region, layer, or section without departing from the teachings of the disclosure. When the second element, component, region, layer, or section is discussed, it does not indicate that the first element, component, region, layer, or section is necessarily present in the disclosure.

Spatially relative terms, such as “beneath”, “below”, “lower”, “under”, “above”, “upper”, and the like, may be used herein for ease of description to describe one element or feature’s relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements or features described as “below”, “beneath” or “under” other elements or features would then be oriented “above” the other elements or features. Therefore, the exemplary term “below” and “beneath” can encompass both orientations of above and below. The device may be otherwise oriented (rotated by 90 degrees or at other orientations) and the spatially relative descriptors used herein are interpreted accordingly.

The terms used herein are intended to describe specific embodiments only and are not intended to constitute a limitation to the disclosure. As used herein, the singular forms “a,” “an”, and “the” are intended to include the plural forms as well, unless the context clearly indicates otherwise. It should also be understood that the terms “comprising” and/or “including”, when used in the specification, identify the presence of the features, integers, steps, operations, components and/or parts, but do not preclude the presence or addition of one or more other features, integers, operations, operations, components, parts and/or groups. As used herein, the term “and/or” in this specification includes any and all combinations of the associated listed items.

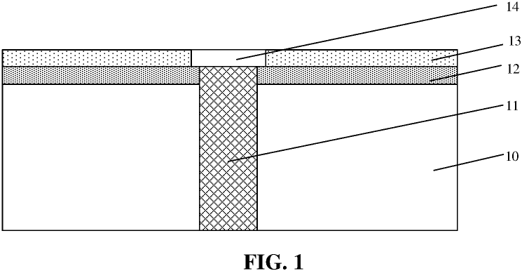

FIG. 1 is a schematic diagram of an exemplary semiconductor structure. As shown in the figure, the semiconductor structure includes: a substrate 10 and an insulating layer 12 located on the substrate 10; a conductive via 11 located in the substrate 10, where an upper surface of the conductive via 11 is flush with an upper surface of the insulating layer 12; a dielectric layer 13 located on the insulating layer 12; and a metal pad 14 located in the dielectric layer 13 and electrically connected to the conductive via 11. When the semiconductor structure is bonded to another structure, the conductive via 11 may provide a vertical interconnect between the semiconductor structure and the another structure.

However, the semiconductor structure is heated when the semiconductor structure is bonded to another structure. In this process, the conductive via 11 protrudes outward from the substrate 10 after thermal expansion, which reduces the flatness of the substrate 10 and affects the performance of the semiconductor structure.

Based on this, the embodiments of the disclosure provide the following technical solutions.

The embodiments of the disclosure provide a semiconductor structure, including: a substrate; a conductive via, a first conductive type transistor and a second conductive type transistor that are located in the substrate; a first metal layer; and a second metal layer. The first conductive type transistor is disposed on two sides of the conductive via in a first direction, and the second conductive type transistor is disposed on two other sides of the conductive via in a second direction, in which the first direction is perpendicular to the second direction. The first metal layer is located on the substrate. The first metal layer includes at least one first metal line extending in the first direction, and the first metal line is electrically connected to a gate of the first conductive type transistor. The second metal layer is located on the first metal layer. The second metal layer includes at least one second metal line extending in the second direction, and the second metal line is electrically connected to a gate of the second conductive type transistor. The first metal line and the second metal line intersect with each other to form a grid structure covering the conductive via.

For the semiconductor structure provided in the embodiments of the disclosure, the grid structure is formed on the conductive via, so that a case that the conductive via protrudes outward after thermal expansion can be mitigated. In addition, the first metal line is connected to the gate of the first conductive type transistor and the second metal line is connected to the gate of the second conductive type transistor, to implement electrical connections.

The semiconductor structure provided in the embodiments of the disclosure may be a Dynamic Random Access Memory (DRAM), but is not limited thereto. The semiconductor structure may be any semiconductor structure with a conductive via.

The specific embodiments of the disclosure are described below in detail with reference to the accompanying drawings. When the embodiments of the disclosure are described in detail, for ease of description, the schematic diagrams are not partially enlarged in accordance with the general scale, and the schematic diagrams are only examples, which should not limit the scope of protection of the disclosure herein.

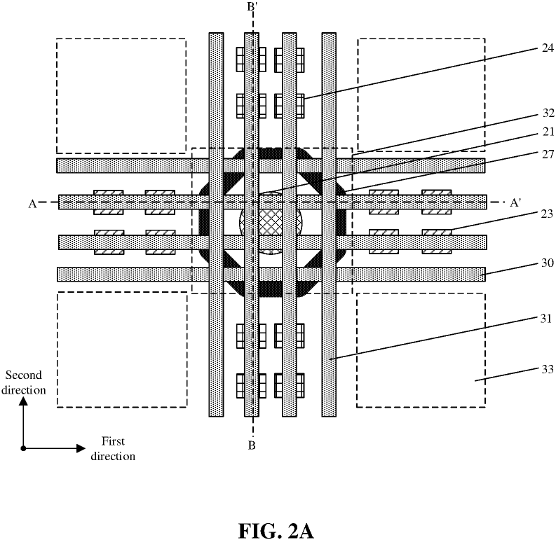

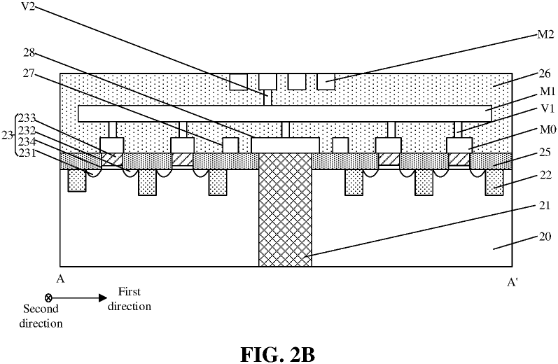

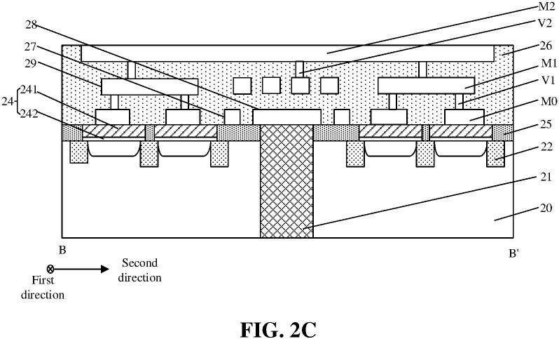

FIG. 2A is a schematic top view of a semiconductor structure according to an embodiment of the disclosure, FIG. 2B is a schematic cross-sectional view of a semiconductor structure according to an embodiment of the disclosure taken along a line A-A' in FIG. 2A, and FIG. 2C is a schematic cross-sectional view of a semiconductor structure according to an embodiment of the disclosure taken along a line B-B' in FIG. 2A. A method for manufacturing a semiconductor structure provided in the embodiments of the disclosure is further described below in detail with reference to FIG. 2A to FIG. 2C.

As shown in the figure, the semiconductor structure includes: a substrate 20; a conductive via 21, a first conductive type transistor 23 and a second conductive type transistor 24 that are located in the substrate 20; a first metal layer M1; and a second metal layer M2. The first conductive type transistor 23 is disposed on two sides of the conductive via 21 in a first direction, and the second conductive type transistor 24 is disposed on two other sides of the conductive via 21 in a second direction, in which the first direction is perpendicular to the second direction. The first metal layer M1 is located on the substrate 20. The first metal layer M1 includes at least one first metal line 30 extending in the first direction, and the first metal line 30 is electrically connected to a gate 233 of the first conductive type transistor 23. The second metal layer M2 is located on the first metal layer M1. The second metal layer M2 includes at least one second metal line 31 extending in the second direction, and the second metal line 31 is electrically connected to a gate 241 of the second conductive type transistor 24. The first metal line 30 and the second metal line 31 intersect with each other to form a grid structure 32 covering the conductive via 21.

The substrate may be a semiconductor substrate, and may include at least one simple substance semiconductor material (for example, a silicon (Si) substrate, or a germanium (Ge) substrate), at least one III-V compound semiconductor material, at least one II-VI compound semiconductor material, at least one organic semiconductor material or other semiconductor materials known in the field. In a specific embodiment, the substrate is a silicon (Si) substrate.

In an actual process, the thickness of the substrate is optionally comprised between 40 µm and 70 µm, for example, between 50 µm and 60 µm.

In an actual process, the conductive via 21 includes a through hole (not marked) penetrating the substrate 20 and a conductive material located in the through hole (not marked). The conductive via 21 is configured to conduct a signal in the semiconductor structure. In an embodiment, an upper surface of the substrate 20 is etched down to form the through hole (not marked), but not limited thereto. The through hole (not marked) may be formed by etching from a rear surface of the substrate 20 to the upper surface of the substrate 20. In some embodiments, the conductive via 21 has a feature dimension comprised between 2 µm and 10 µm and a depth comprised between 5 µm and 100 µm.

The conductive via is subject to a cooling process from a high temperature to a low temperature during manufacturing. In the cooling process, the conductive via and the substrate contract to different degrees, generating stress in the substrate. The stress affects the moving speed of current carriers in the substrate near the conductive via. Therefore, when designing a semiconductor structure, a technician usually arranges a keep out zone (KOZ) around the conductive via. An active device such as a transistor is not arranged in the KOZ. The diameter of the KOZ is usually comprised between 5 µm and 15 µm with the center of the conductive via being the center of circle. It may be understood that the presence of the KOZ reduces the utilization of the substrate.

The applicant finds through research that when transistors with different conductive types are appropriately arranged in the KOZ, the utilization of the KOZ can be improved, and some performance of the semiconductor structure can be further improved. For example, in an embodiment of the disclosure, an n-type transistor is arranged on two sides of the conductive via in the first direction, and a channel direction of the n-type transistor is parallel to the first direction. A p-type transistor is disposed on two other sides of the conductive via in the second direction, and a channel direction of the p-type transistor is perpendicular to the second direction. In this way, both the mobility in the n-type transistor and the mobility in the p-type transistor can be improved, thereby further increasing the conduction speed of the n-type transistor and the conduction speed of the p-type transistor. Optionally, the n-type transistor and the p-type transistor are connected to each other by the first metal layer and the second metal layer to form an inverter. An input end of the inverter is electrically connected to the conductive via. That is, a signal is conducted through the conductive via to the input end of the inverter. The n-type transistor and the p-type transistor forming the inverter have relatively high mobility, so that the inverter has a relatively high conduction speed, thereby increasing a transmission speed of a signal.

In another embodiment of the disclosure, the n-type transistor is arranged on two sides of the conductive via in the first direction, and a channel direction of the n-type transistor is perpendicular to the first direction. The p-type transistor is disposed on two other sides of the conductive via in the second direction, and a channel direction of the p-type transistor is parallel to the second direction. In this way, both the mobility in the n-type transistor and the mobility in the p-type transistor can be reduced, to reduce leakage currents flowing through the n-type transistor and the p-type transistor, thereby reducing the power consumption of the semiconductor structure. Optionally, the n-type transistor and the p-type transistor are connected to each other by the first metal layer and the second metal layer to form an inverter. An input end of the inverter is electrically connected to the conductive via. That is, a signal is conducted through the conductive via to the input end of the inverter. The n-type transistor and the p-type transistor forming the inverter have relatively low mobility, so that the inverter has a relatively small leakage current, thereby reducing the power consumption of the semiconductor structure.

It needs to be noted that the selection of the first direction is related to the crystal orientation of the surface of the substrate. In an embodiment of the disclosure, the first direction may be parallel to the crystal orientation of the surface of the substrate.

Referring to FIG. 2B and FIG. 2C, the first conductive type transistor 23 includes the gate 233, a gate dielectric layer 234, a first source/drain doped area 231, and a second source/drain doped area 232. The second conductive type transistor 24 includes the gate 241, a gate dielectric layer 242, a first source/drain doped area (not shown in the figure), and a second source/drain doped area (not shown in the figure).

In an embodiment, the semiconductor structure further includes an insulating layer 25 located on the substrate 20 and an isolation structure 22 located in the substrate 20.

Specifically, the insulating layer is located between the gate of the first conductive type transistor and the gate of the second conductive type transistor. An upper surface of the insulating layer is flush with an upper surface of the gate of the first conductive type transistor and an upper surface of the gate of the second conductive type transistor. The insulating layer is configured to electrically isolate the gate of the first conductive type transistor from the gate of the second conductive type transistor. The insulating layer is further configured to protect the substrate from oxidation, nitridation, damage, contamination, or the like. The isolation structure is configured to electrically isolate device structures, which are located in the substrate and are adjacent to each other, from each other. The isolation structure may be, for example, a shallow trench isolation structure. The device structures may be transistors formed in the substrate, for example, the first conductive type transistor and the second conductive type transistor in the embodiments of the disclosure.

As shown in FIG. 2A, the substrate 20 includes a corner area 33 disposed between the first conductive type transistor 23 and the second conductive type transistor 24. A distance between the corner area 33 and the conductive via 21 is comprised between 1 micrometer and 20 micrometers. In an example, the semiconductor structure further includes a passive device (not shown in the figure). The passive device (not shown in the figure) is disposed in the corner area 33 of the substrate 20. The passive device (not shown in the figure) includes, but not limited to, a resistor, or a capacitor. The passive device (not shown in the figure) insensitive to the stress is disposed in the corner area 33, which can improve the utilization of the KOZ.

There are a plurality of first metal lines 30, and the plurality of first metal lines 30 are regularly arranged in the second direction; and/or there are a plurality of second metal lines 31, and the plurality of second metal lines 31 are regularly arranged in the first direction. In a specific embodiment, a spacing between any two adjacent first metal lines 30 of the plurality of first metal lines 30 is comprised between 0.5 micrometers and 2 micrometers; and/or a spacing between any two adjacent second metal lines 31 of the plurality of second metal lines 31 is comprised between 0.5 micrometers and 2 micrometers.

Referring to FIG. 2B and FIG. 2C, the semiconductor structure further includes an intermediate metal layer M0 and conductive plugs V1, V2. The intermediate metal layer M0 is located between the first metal layer M1 and the substrate 20. The conductive plugs V1, V2 include at least one first sub-plug V1 located between the intermediate metal layer M0 and the first metal layer M1, and at least one second sub-plug V2 located between the first metal layer M1 and the second metal layer M2.

In a specific embodiment, the intermediate metal layer M0 includes a metal pad 28. The metal pad 28 is located on an upper surface of the conductive via 21. The at least one first metal line 30 is electrically connected to the metal pad 28 by the first sub-plug V1. In this way, a signal may be conducted to the first metal line 30 through the conductive via 21.

In a more specific embodiment, the first metal line 30 is electrically connected to the gate 233 of the first conductive type transistor 23 in the following manner: the first metal line 30 is electrically connected to the gate 233 of the first conductive type transistor 23 by the first sub-plug V1 and the intermediate metal layer M0. In this way, a signal may be conducted to the gate 233 of the first conductive type transistor 23 through the conductive via 21.

In addition, the first metal layer M1 further includes a first wiring structure 29. The second metal line 31 is electrically connected to the gate 241 of the second conductive type transistor 24 in the following manner: the second metal line 31 is electrically connected to the gate 241 of the second conductive type transistor 24 by the second sub-plug V2, the first wiring structure 29, the first sub-plug V1, and the intermediate metal layer M0, as shown in FIG. 2C.

The at least one first metal line 30 and the at least one second metal line 31 may be electrically connected to each other by the second sub-plug V2 at an intersection of the at least one first metal line 30 and the at least one second metal line 31. In this way, a signal is conducted to the gate 241 of the second conductive type transistor 24 through the conductive via 21.

In an embodiment, the semiconductor structure further includes an annular shielding layer 27. The annular shielding layer 27 is disposed around the conductive via 21, as shown in FIG. 2A. The annular shielding layer 27 is configured to mitigate a crosstalk effect generated during signal transmission between the conductive via 21 and a metal conductive structure near the conductive via.

In a specific embodiment, there is one annular shielding layer 27, as shown in FIG. 2B and FIG. 2C. Optionally, the annular shielding layer 27 and the intermediate metal layer M0 are simultaneously formed in the same process operation. However, the disclosure is not limited thereto, and there may be a plurality of annular shielding layers 27.

In an embodiment, the semiconductor structure further includes a dielectric layer 26. The dielectric layer 26 covers the intermediate metal layer M0, the first metal layer M1, the second metal layer M2, the annular shielding layer 27, the first sub-plug V1, and the second sub-plug V2.

It needs to be noted that the dielectric layer 26 is not a single-layer structure, and is formed by a plurality of layers of insulating material in a plurality of process operations.

In the embodiments of the disclosure, the first metal line and the second metal line intersect with each other to form a grid structure covering the conductive via, so that a case that the conductive via protrudes outward after thermal expansion can be mitigated. In addition, in the embodiments of the disclosure, the first conductive type transistor and the second conductive type transistor are appropriately arranged around the KOZ of the conductive via. The first conductive type transistor and the second conductive type transistor are electrically connected to each other by the first metal line and the second metal line to form a device such as an inverter, so that the utilization of the substrate can be improved, and some performance of the device can be improved. For example, the conduction speed of the device can be increased, and the power consumption of the device can be reduced.

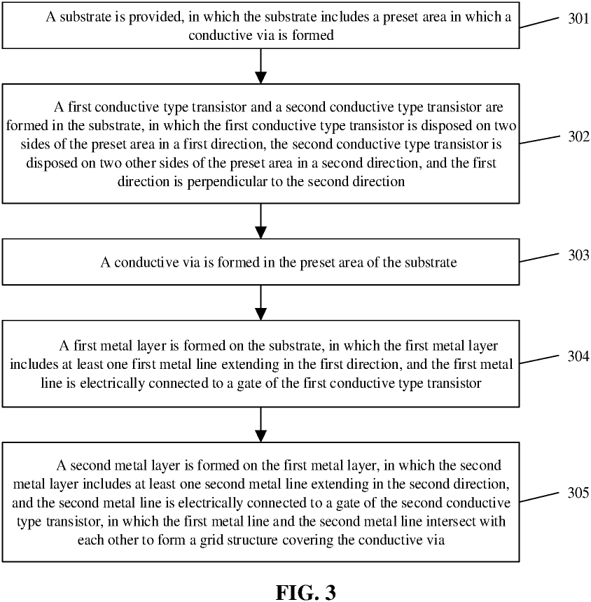

The embodiments of the disclosure further provide a method for manufacturing a semiconductor structure. As shown in FIG. 3, the method includes the following operations.

At S301, a substrate is provided, in which the substrate includes a preset area in which a conductive via is formed.

At S302, a first conductive type transistor and a second conductive type transistor are formed in the substrate, in which the first conductive type transistor is disposed on two sides of the preset area in a first direction, the second conductive type transistor is disposed on two other sides of the preset area in a second direction, and the first direction is perpendicular to the second direction.

At S303, a conductive via is formed in the preset area of the substrate.

At S304, a first metal layer is formed on the substrate, in which the first metal layer includes at least one first metal line extending in the first direction, and the first metal line is electrically connected to a gate of the first conductive type transistor.

At S305, a second metal layer is formed on the first metal layer, in which the second metal layer includes at least one second metal line extending in the second direction, and the second metal line is electrically connected to a gate of the second conductive type transistor, in which the first metal line and the second metal line intersect with each other to form a grid structure covering the conductive via.

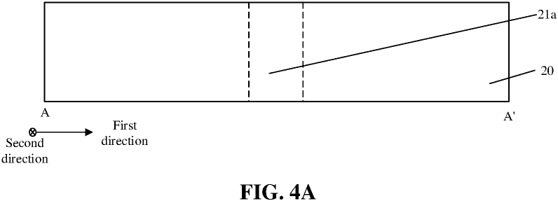

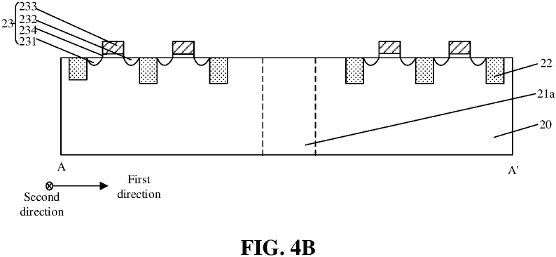

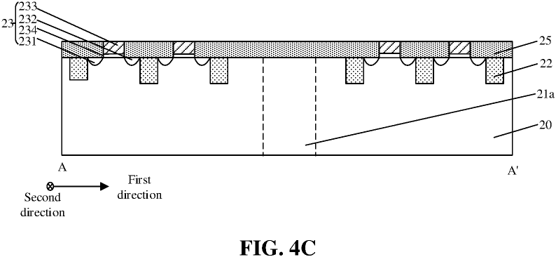

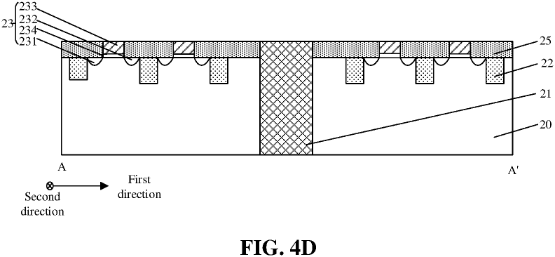

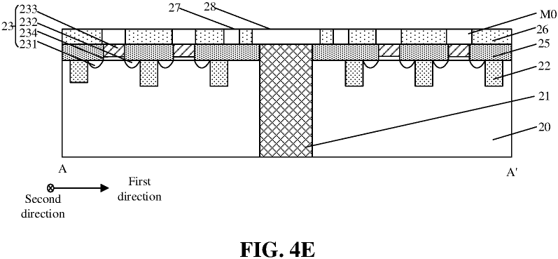

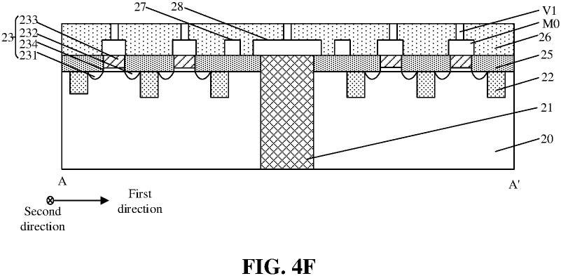

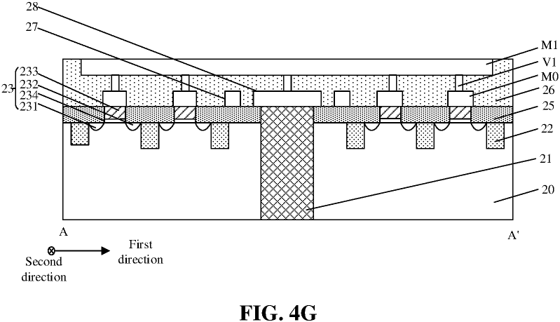

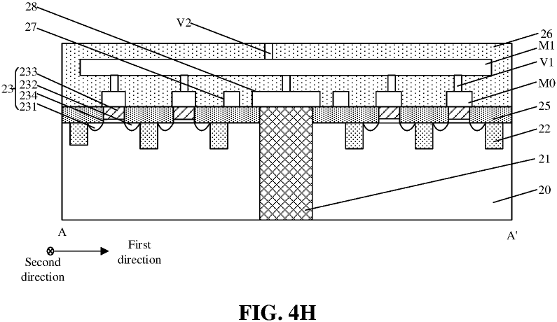

The method for manufacturing the semiconductor structure in the embodiments of the disclosure is further described below in detail with reference to FIG. 4A to FIG. 4H.

First, S301 is performed. At S301, the substrate 20 is provided, in which the substrate 20 includes a preset area 21a in which a conductive via 21 (referring to FIG. 4D) is formed, as shown in FIG. 4A.

The substrate may be a semiconductor substrate, and may include at least one simple substance semiconductor material (for example, a silicon (Si) substrate, or a germanium (Ge) substrate), at least one III-V compound semiconductor material, at least one II-VI compound semiconductor material, at least one organic semiconductor material or other semiconductor materials known in the field. In some embodiments, in a specific embodiment, the substrate is a silicon (Si) substrate.

In an actual process, the thickness of the substrate is optionally comprised between 40 µm and 70 µm, for example, between 50 µm and 60 µm.

In an embodiment, the preset area 21a is a cylindrical area. The diameter of the cylindrical area is comprised between 2 µm and 10 µm.

Next, S302 is performed. At S302, a first conductive type transistor 23 and a second conductive type transistor 24 are formed in the substrate 20, in which the first conductive type transistor 23 is disposed on two sides of the preset area 21a in the first direction, the second conductive type transistor 24 is disposed on two other sides of the preset area 21a in the second direction, and the first direction is perpendicular to the second direction, as shown in FIG. 4B.

The first conductive type transistor 23 may be, for example, an n-type transistor. The second conductive type transistor 24 may be, for example, a p-type transistor.

A conductive via is formed in the preset area in the subsequent process. The conductive via is subject to a cooling process from a high temperature to a low temperature during manufacturing. In the cooling process, the conductive via and the substrate contract to different degrees, generating stress in the substrate. The stress affects the moving speed of current carriers in the substrate near the conductive via. Therefore, when designing a semiconductor structure, a technician usually arranges a KOZ around the conductive via. An active device such as a transistor is not arranged in the KOZ. The diameter of the KOZ is usually comprised between 5 µm and 15 µm with the center of the conductive via being the center of circle. It may be understood that the presence of the KOZ reduces the utilization of the substrate.

The applicant finds through research that when transistors with different conductive types are appropriately arranged in the KOZ, the utilization of the KOZ can be improved, and some performance of the semiconductor structure can be further improved. For example, in an embodiment of the disclosure, the n-type transistor is arranged on two sides of the conductive via in the first direction, and a channel direction of the n-type transistor is parallel to the first direction. The p-type transistor is disposed on two other sides of the conductive via in the second direction, and a channel direction of the p-type transistor is perpendicular to the second direction. In this way, both the mobility in the n-type transistor and the mobility in the p-type transistor can be improved, thereby further increasing the conduction speed of the n-type transistor and the conduction speed of the p-type transistor.

In another embodiment of the disclosure, the n-type transistor is arranged on two sides of the conductive via in the first direction, and a channel direction of the n-type transistor is perpendicular to the first direction. The p-type transistor is disposed on two other sides of the conductive via in the second direction, and a channel direction of the p-type transistor is parallel to the second direction. In this way, both the mobility in the n-type transistor and the mobility in the p-type transistor can be reduced, to reduce leakage currents flowing through the n-type transistor and the p-type transistor, thereby reducing the power consumption of the semiconductor structure.

It needs to be noted that the selection of the first direction is related to the crystal orientation of the surface of the substrate. In an embodiment of the disclosure, the first direction may be parallel to the crystal orientation of the surface of the substrate.

Specifically, the first conductive type transistor 23 includes a gate 233, a gate dielectric layer 234, a first source/drain doped area 231, and a second source/drain doped area 232, as shown in FIG. 4B. The second conductive type transistor 24 includes a gate 241, a gate dielectric layer 242, a first source/drain doped area (not shown in the figure), and a second source/drain doped area (not shown in the figure), as shown in FIG. 2C.

With reference to FIG. 4B again, in an embodiment, the method further includes the following operation. An isolation structure 22 is formed in the substrate 20. In a specific embodiment, the isolation structure 22 is formed before the first conductive type transistor 23 and the second conductive type transistor 24 are formed. The isolation structure 22 is configured to electrically isolate device structures, which are located in the substrate 20 and are adjacent to each other, from each other. The isolation structure 22 may be, for example, a shallow trench isolation structure. The device structures may be transistors formed in the substrate 20, for example, the first conductive type transistor 23 and the second conductive type transistor 24 in the embodiments of the disclosure.

As shown in FIG. 4C, after the first conductive type transistor 23 and the second conductive type transistor 24 are formed in the substrate 20, the method further includes the operation that an insulating layer 25 is formed on the substrate 20.

Specifically, the insulating layer is formed between the gate of the first conductive type transistor and the gate of the second conductive type transistor. An upper surface of the insulating layer is flush with an upper surface of the gate of the first conductive type transistor and an upper surface of the gate of the second conductive type transistor. The insulating layer is configured to electrically isolate the gate of the first conductive type transistor from the gate of the second conductive type transistor. The insulating layer is further configured to protect the substrate from oxidation, nitridation, damage, contamination, or the like.

In an embodiment, the substrate 20 further includes a corner area 33 disposed between the first conductive type transistor 23 and the second conductive type transistor 24. A distance between the corner area 33 and the conductive via 21 (referring to FIG. 4D) is comprised between 1 micrometer and 20 micrometers, as shown in FIG. 2A. In a specific example, the semiconductor structure further includes a passive device (not shown in the figure). The passive device (not shown in the figure) is disposed in the corner area 33 of the substrate 20. The passive device (not shown in the figure) includes, but not limited to, a resistor, or a capacitor. The passive device (not shown in the figure) insensitive to the stress is disposed in the corner area 33, which can improve the utilization of the KOZ.

Next, S303 is performed. At S303, the conductive via 21 is formed in the preset area 21a of the substrate 20, as shown in FIG. 4D.

Specifically, a method for forming the conductive via 21 includes the following operations. A through hole is formed in the substrate 20, in which the through hole penetrates the substrate 20 and the insulating layer 25. A conductive material is formed in the through hole to form the conductive via 21. The conductive via 21 is configured to conduct a signal in the semiconductor structure. The conductive material may be copper. In some embodiments, the conductive via 21 has a feature dimension comprised between 2 µm and 10 µm and a depth comprised between 5 µm and 100 µm.

More specifically, the conductive via further includes an insulating film formed on an inner wall of the through hole, and a barrier layer formed between the insulating film and the conductive material. The material of the insulating film may be oxide, for example, silicon oxide. The thickness of the insulating film is comprised between 2000 Å and 5000 Å. The barrier layer may be made of a metal, for example, tantalum. The thickness of the barrier layer is comprised between 2000 Å and 5000 Å.

Next, S304 is performed. At S304, a first metal layer M1 is formed on the substrate 20, in which the first metal layer M1 includes the at least one first metal line 30 extending in the first direction, and the first metal line 30 is electrically connected to a gate 233 of the first conductive type transistor 23, as shown in FIG. 4G.

Specifically, the operation that the first metal layer M1 is formed on the substrate 20 includes the following operations.

A dielectric layer 26 is formed on the substrate, the dielectric layer 26 is patterned, and the first metal layer M1 is formed in the patterned dielectric layer.

In an embodiment, there are a plurality of first metal lines 30, and the plurality of first metal lines 30 are regularly arranged in the second direction. In a specific embodiment, a spacing between any two adjacent first metal lines 30 of the plurality of first metal lines 30 is comprised between 0.5 micrometers and 2 micrometers.

In an embodiment, the semiconductor structure further includes an intermediate metal layer M0 and a first sub-plug V1. before the first metal layer M1 is formed on the substrate 20, the method includes the following operations.

An intermediate metal layer M0 is formed on the substrate 20, in which the intermediate metal layer M0 is electrically connected to the gate 233 of the first conductive type transistor 23 and the gate 241 of the second conductive type transistor 24, as shown in FIG. 4E.

A first sub-plug V1 is formed on the intermediate metal layer M0, in which the first sub-plug V1 is configured to electrically connect the first metal layer M1 and the intermediate metal layer M0 with each other, as shown in FIG. 4F.

In a specific embodiment, the operation that the intermediate metal layer M0 and the first sub-plug V1 are formed includes the following operations.

A dielectric layer is formed on the substrate, the dielectric layer is patterned, and the intermediate metal layer M0 is formed in the patterned dielectric layer.

A dielectric layer covering the intermediate metal layer M0 is formed, a through hole is formed in the dielectric layer, and the first sub-plug V1 is formed in the through hole.

In an embodiment, the intermediate metal layer M0 includes a metal pad 28. The metal pad 28 is located on an upper surface of the conductive via 21. The at least one first metal line 30 is electrically connected to the metal pad 28 by the first sub-plug V1. In this way, a signal may be conducted to the first metal line 30 through the conductive via 21.

In a specific embodiment, the first metal line 30 is electrically connected to the gate 233 of the first conductive type transistor 23 in the following manner: the first metal line 30 is electrically connected to the gate 233 of the first conductive type transistor 23 by the first sub-plug V1 and the intermediate metal layer M0. In this way, a signal may be conducted to the gate 233 of the first conductive type transistor 23 through the conductive via 21.

In an embodiment, the first metal layer M1 further includes a first wiring structure 29. The first wiring structure 29 is electrically connected to the intermediate metal layer M0 by the first sub-plug V1, as shown in FIG. 2C.

With reference to FIG. 4E again, in an embodiment, the method further includes the following operation. An annular shielding layer 27 is formed on the substrate 20, in which the annular shielding layer 27 is disposed around the conductive via 21. The annular shielding layer 27 is configured to mitigate a crosstalk effect generated during signal transmission between the conductive via 21 and a metal conductive structure near the conductive via. In a specific embodiment, there is one annular shielding layer 27. The annular shielding layer 27 and the intermediate metal layer M0 are simultaneously formed in the same process operation. However, the disclosure is not limited thereto, and there may be a plurality of annular shielding layers 27.

Finally, S305 is performed. At S305, a second metal layer M2 is formed on the first metal layer M1, in which the second metal layer M2 includes at least one second metal line 31 extending in the second direction, and the second metal line 31 is electrically connected to a gate 241 of the second conductive type transistor 24. The first metal line 30 and the second metal line 31 intersect with each other to form a grid structure 32 covering the conductive via 21, as shown in FIG. 2A to FIG. 2C.

Specifically, the operation that the second metal layer M2 is formed on the first metal layer M1 includes the following operations.

A dielectric layer covering the first metal layer is formed, the dielectric layer is patterned, and the second metal layer M2 is formed in the patterned dielectric layer.

In an embodiment, there are a plurality of second metal lines 31, and the plurality of second metal lines 31 are regularly arranged in the first direction. In a specific embodiment, a spacing between any two adjacent second metal lines 31 of the plurality of second metal lines 31 is comprised between 0.5 micrometers and 2 micrometers.

In an embodiment, the semiconductor structure further includes a second sub-plug V2. Before the second metal layer M2 is formed on the first metal layer M1, the method includes the following operation. The second sub-plug V2 is formed on the first metal layer M1, in which the second sub-plug V2 is configured to electrically connect the first metal layer M1 and the second metal layer M2 with each other, as shown in FIG. 4H.

Specifically, the operation that the second sub-plug V2 is formed on the first metal layer M1 includes the following operations.

A dielectric layer is formed on the first metal layer M1, a through hole is formed in the dielectric layer, and the second sub-plug V2 is formed in the through hole.

In an embodiment, the second metal line 31 is electrically connected to the gate 241 of the second conductive type transistor 24 in the following manner: the second metal line 31 is electrically connected to the gate 241 of the second conductive type transistor 24 by the second sub-plug V2, the first wiring structure 29, the first sub-plug V1, and the intermediate metal layer M0.

In a specific embodiment, the at least one first metal line 30 and the at least one second metal line 31 are electrically connected to each other by the second sub-plug V2 at an intersection of the at least one first metal line 30 and the at least one second metal line 31. In this way, a signal is conducted to the gate 241 of the second conductive type transistor 24 through the conductive via 21.

It should be noted that a person skilled in the art can change the above sequence of operations without departing from the scope of protection of the disclosure. The foregoing is merely optional embodiments of the disclosure but is not used to limit the scope of protection of the disclosure. Any changes, equivalent replacements, and improvements made within the spirit and principle of the disclosure shall fall within the protection scope of the disclosure.

What is claimed is:

1. A semiconductor structure, comprising:
a substrate;
a conductive via, a first conductive type transistor, and a second conductive type transistor that are located in the substrate, wherein the first conductive type transistor is disposed on two sides of the conductive via in a first direction, the second conductive type transistor is disposed on two other sides of the conductive via in a second direction, and the first direction is perpendicular to the second direction;
a first metal layer located on the substrate, wherein the first metal layer comprises at least one first metal line extending in the first direction, and the first metal line is electrically connected to a gate of the first conductive type transistor; and
a second metal layer located on the first metal layer, wherein the second metal layer comprises at least one second metal line extending in the second direction, and the second metal line is electrically connected to a gate of the second conductive type transistor,
wherein the first metal line and the second metal line intersect with each other to form a grid structure covering the conductive via.

2. The semiconductor structure according to claim 1, wherein the first metal layer comprises a plurality of first metal lines, and the plurality of first metal lines are regularly arranged in the second direction.

3. The semiconductor structure according to claim 2, wherein a spacing between any two adjacent first metal lines of the plurality of first metal lines is comprised between 0.5 micrometers and 2 micrometers.

4. The semiconductor structure according to claim 1, wherein the first conductive type transistor is an n-type transistor, and the second conductive type transistor is a p-type transistor.

5. The semiconductor structure according to claim 4, wherein a channel direction of the first conductive type transistor is parallel to the first direction, and a channel direction of the second conductive type transistor is perpendicular to the second direction.

6. The semiconductor structure according to claim 4, wherein a channel direction of the first conductive type transistor is perpendicular to the first direction, and a channel direction of the second conductive type transistor is parallel to the second direction.

7. The semiconductor structure according to claim 1, wherein the semiconductor structure further comprises an intermediate metal layer and conductive plugs, the intermediate metal layer is located between the first metal layer and the substrate, and the conductive plugs comprise at least one first sub-plug located between the intermediate metal layer and the first metal layer, and at least one second sub-plug located between the first metal layer and the second metal layer.

8. The semiconductor structure according to claim 7, wherein the first metal line is electrically connected to the gate of the first conductive type transistor in a manner that the first metal line is electrically connected to the gate of the first conductive type transistor by the first sub-plug and the intermediate metal layer.

9. The semiconductor structure according to claim 7, wherein the first metal layer further comprises a first wiring structure, and the second metal line is electrically connected to the gate of the second conductive type transistor in a manner that the second metal line is electrically connected to the gate of the second conductive type transistor by the second sub-plug, the first wiring structure, the first sub-plug and the intermediate metal layer.

10. The semiconductor structure according to claim 7, wherein the at least one first metal line and the at least one second metal line are electrically connected to each other by the second sub-plug at an intersection of the at least one first metal line and the at least one second metal line.

11. The semiconductor structure according to claim 7, wherein the intermediate metal layer comprises a metal pad, and the metal pad is located on an upper surface of the conductive via, and
the at least one first metal line is electrically connected to the metal pad by the first sub-plug.

12. The semiconductor structure according to claim 1, wherein the substrate comprises a corner area disposed between the first conductive type transistor and the second conductive type transistor, and a distance between the corner area and the conductive via is comprised between 1 micrometer and 20 micrometers.

13. The semiconductor structure according to claim 12, wherein the semiconductor structure further comprises a passive device disposed in the corner area of the substrate.

14. The semiconductor structure according to claim 1, wherein the second metal layer comprises a plurality of second metal lines, and the plurality of second metal lines are regularly arranged in the first direction.

15. The semiconductor structure according to claim 1, wherein the first metal layer comprises a plurality of first metal lines, and the plurality of first metal lines are regularly arranged in the second direction; and the second metal layer comprises a plurality of second metal lines, and the plurality of second metal lines are regularly arranged in the first direction.

16. The semiconductor structure according to claim 14, wherein a spacing between any two adjacent second metal lines of the plurality of second metal lines is comprised between 0.5 micrometers and 2 micrometers.

17. The semiconductor structure according to claim 15, wherein a spacing between any two adjacent first metal lines of the plurality of first metal lines is comprised between 0.5 micrometers and 2 micrometers; and a spacing between any two adjacent second metal lines of the plurality of second metal lines is comprised between 0.5 micrometers and 2 micrometers.

18. A method for manufacturing a semiconductor structure, comprising:
providing a substrate, wherein the substrate comprises a preset area in which a conductive via is formed;
forming a first conductive type transistor and a second conductive type transistor in the substrate, wherein the first conductive type transistor is disposed on two sides of the preset area in a first direction, the second conductive type transistor is disposed on two other sides of the preset area in a second direction, and the first direction is perpendicular to the second direction;
forming a conductive via in the preset area of the substrate;
forming a first metal layer on the substrate, wherein the first metal layer comprises at least one first metal line extending in the first direction, and the first metal line is electrically connected to a gate of the first conductive type transistor; and
forming a second metal layer on the first metal layer, wherein the second metal layer comprises at least one second metal line extending in the second direction, and the second metal line is electrically connected to a gate of the second conductive type transistor,
wherein the first metal line and the second metal line intersect with each other to form a grid structure covering the conductive via.

19. The method according to claim 18, wherein the semiconductor structure further comprises an intermediate metal layer and a first sub-plug, and wherein before forming the first metal layer on the substrate, the method comprises:
forming the intermediate metal layer on the substrate, wherein the intermediate metal layer is electrically connected to the gate of the first conductive type transistor and the gate of the second conductive type transistor; and
forming the first sub-plug on the intermediate metal layer, wherein the first sub-plug is configured to electrically connect the first metal layer and the intermediate metal layer with each other.

20. The method according to claim 18, wherein the semiconductor structure further comprises a second sub-plug, and wherein before forming the second metal layer on the first metal layer, the method comprises:
forming the second sub-plug on the first metal layer, wherein the second sub-plug is configured to electrically connect the first metal layer and the second metal layer with each other.
